(19) United States
(12) Patent Application Publication
(10) Pub. No.: US 2026/0106607 A1
(43) Pub. Date: Apr. 16, 2026

(54) SEMICONDUCTOR DEVICE

(71) Applicant: Renesas Electronics Corporation, Tokyo (JP)

(72) Inventor: Hirotoshi MINE, Tokyo (JP)

(21) Appl. No.: 19/331,215

(22) Filed: Sep. 17, 2025

(30) Foreign Application Priority Data
Oct. 11, 2024 (JP) 2024-178794

(51) Int. Cl. H03K 5/1534; H03K 5/00; H03K 19/21; H03K 23/54

(52) U.S. Cl. CPC H03K 5/1534; H03K 23/54; H03K 2005/00058; H03K 2005/00247; H03K 19/21

(57) ABSTRACT

A semiconductor device includes a pulse input circuit including flip-flops constituting each of two front-stage counters having different holding states from each other and configured such that first pulses from an even-stage ring circuit are input to each of the two front-stage counters, an edge detection circuit configured to detect edges of outputs of the two front-stage counters and output a second pulse having a predetermined pulse width larger than a predetermined value based on the edge, and a counter circuit including a rear-stage counter to which the second pulse is input. The edge detection circuit is configured to output the second pulse or a stepwise signal when a pulse width of the first pulse is smaller than the predetermined value.

### CROSS-REFERENCE TO RELATED APPLICATIONS

The disclosure of Japanese Patent Application No. 2024-178794 filed on Oct. 11, 2024 including the specification, drawings and abstract is incorporated herein by reference in its entirety.

### BACKGROUND

The present invention relates to a semiconductor device.

There is disclosed a technique listed below.
[Non-Patent Document 1] Kaiyuan Yang, David Blaauw, Dennis Sylvester, “A Robust-40 to 120° C. All-Digital True Random Number Generator in 40 nm CMOS”, Symposium on VLSI Circuits, VLSIC 2015, Kyoto, Japan, June 17-19, 2015. pages 248, IEEE, 2015.

Non-Patent Document 1 discloses a technique for generating true random numbers using an even-stage ring circuit.

### SUMMARY

Since pulses generated by an even-stage ring circuit have a small pulse width, there is a problem of having difficulty in stably counting the pulses.

This disclosure has been made in order to solve such a problem, and an object thereof is to realize a semiconductor device capable of stably counting the pulses output from an even-stage ring circuit.

Other problems and novel features will be apparent from the description of this specification and accompanying drawings.

A semiconductor device according to one embodiment includes a pulse input circuit including flip-flops constituting each of two front-stage counters having different holding states from each other and configured such that first pulses from an even-stage ring circuit are input to each of the two front-stage counters, an edge detection circuit configured to detect edges of outputs of the two front-stage counters and output a second pulse having a predetermined pulse width larger than a predetermined value based on the edge, and a counter circuit including a rear-stage counter to which the second pulse is input, and the edge detection circuit is configured to output the second pulse or a stepwise signal when a pulse width of the first pulse is smaller than the predetermined value.

According to the above embodiment, it is possible to provide a semiconductor device capable of stably counting the pulses output from an even-stage ring circuit.

### BRIEF DESCRIPTION OF THE DRAWINGS

FIG. 1 is a circuit diagram of an even-stage ring circuit.

FIG. 2 is a graph illustrating a waveform of a pulse output from the even-stage ring circuit.

FIG. 3 is an explanatory diagram of a configuration of a circuit that generates a true random number seed.

FIG. 4 is an explanatory diagram of variations in minimum pulse width of a pulse capable of operating a counter.

FIG. 5 is an explanatory diagram of the variation in minimum pulse width due to the holding state of a counter.

FIG. 6 is an explanatory diagram of the simulation result of count values by counter circuits connected to the even-stage ring circuit.

FIG. 7 is a circuit diagram of a semiconductor device according to the first embodiment.

FIG. 8 is an explanatory diagram of an operation of the semiconductor device according to the first embodiment.

FIG. 9 is an explanatory diagram of the variations in minimum pulse width in the semiconductor device according to the first embodiment.

FIG. 10 is an explanatory diagram of the verification result of the operation of the semiconductor device according to the first embodiment.

FIG. 11 is a circuit diagram of a semiconductor device according to the second embodiment.

FIG. 12 is an explanatory diagram of an operation of the semiconductor device according to the second embodiment.

FIG. 13 is a circuit diagram of a semiconductor device according to the third embodiment.

### DETAILED DESCRIPTION

In order to clarify the explanation, the following description and drawings are omitted and simplified as appropriate. In each drawing, the same elements are denoted by the same reference characters, and duplicate descriptions are omitted as necessary. In addition, each element illustrated in the drawings as a functional block that performs various processes can be configured of a CPU (Central Processing Unit), memory, and other circuits in hardware, and is realized by a program loaded into the memory in software. Therefore, it is understood by those skilled in the art that these functional blocks can be realized in various forms by hardware, software running on the hardware, or a combination thereof, and are not limited to any one of them.

### Problem Newly Found by Inventor

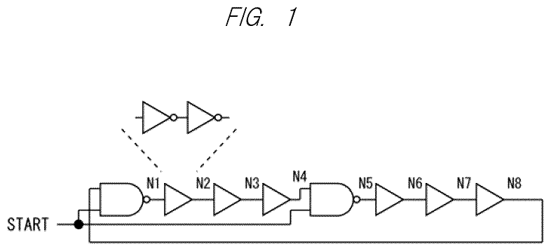

Security measures have become indispensable in recent SoC (System-on-a-chip), and true random number generation is a core function thereof. Several true random number seed circuits have been proposed, and the even-stage ring circuit is one of them. In the even-stage ring circuit illustrated in FIG. 1, the buffer logic is configured with two stages of inverter logic. Considering the buffer logic and NAND inverter logic, the even-stage ring circuit in FIG. 1 has a total of 14 stages.

In the even-stage ring circuit, edges (for example, rising edge and falling edge) are generated at two points in the ring by inputting H, that is, “1” to the START terminal. The pulse corresponding to the edges of two points goes around the circuit while gradually decreasing or increasing the pulse width, and finally the two edges collide and the pulse disappears. Thermal noise causes variation in the number of times the pulse disappears and goes around and the places where the pulse disappears, and this variation can be used as a seed for the true random number.

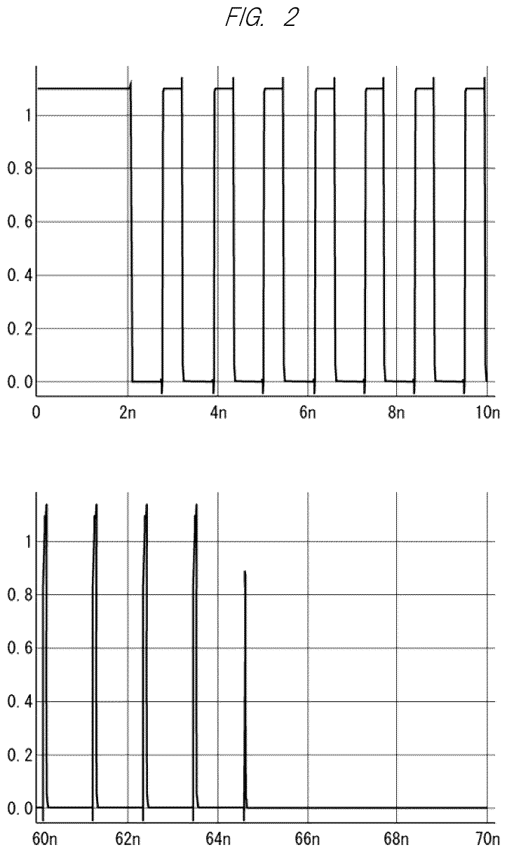

In order to observe the pulse, a counter circuit is connected to one or more nodes (for example, N1 to N8) of the even-stage ring circuit. FIG. 2 illustrates the simulation waveform of this pulse. The upper part of FIG. 2 illustrates the waveform of the pulse from 0 ns to 10 ns, and the lower part illustrates the waveform of the pulse after 60 ns. At 2 ns, “1” is input to the START terminal and a pulse is generated. The two edges gradually approach each other, and at approximately 65 ns, the two edges collide and the pulse disappears. As the pulse disappears, the pulse width may become extremely small.

The even-stage ring circuit and the counter circuit are implemented using an automatic place-and-route tool. Since an automatic place-and-route tool is used, the amount of fluctuation in the pulse width that leads to the disappearance of the pulse is greatly affected by the implementation situation, and a state in which the count value of one or more flip-flop counters connected to the nodes of the even-stage ring circuit is always 1 (or always 0) occurs due to the Min pulse width characteristics that depend on the holding state of flip-flop. The Min pulse width refers to the minimum pulse width of the pulse that can change the holding state of the flip-flop counter.

If the count value is always 1, the count value cannot be used as the true random number seed. In order to avoid such a state, it is necessary to extract the netlist with the parasitic capacitance and resistance of each of the even-stage ring circuit and counter circuits implemented by the automatic place-and-route tool, and perform a transistor-level analysis, resulting in the occurrence of problem of requiring a lot of man-hours and time.

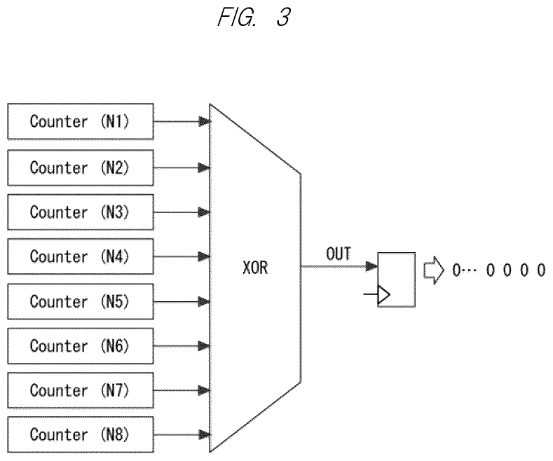

FIG. 3 illustrates an example of a circuit configured to generate random number seeds. A counter circuit is connected to each of the nodes N1 to N8 of the even-stage ring circuit in FIG. 1. The XOR gate aggregates the outputs of the counter circuits into 1 bit. When the count values of all the counter circuits are 1, the output of the XOR gate is always 0, so the counter circuit placed after the XOR gate always outputs 0.

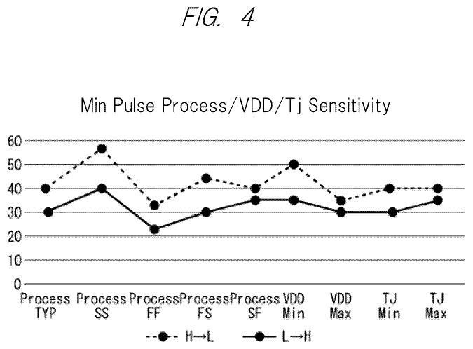

FIG. 4 illustrates variations of Min pulse width depending on the process, the power supply voltage VDD, and the junction temperature Tⱼ. The vertical axis represents the Min pulse width [ps]. The inventor of this application performed the simulation with a power supply voltage of 1.1 V and a junction temperature Tⱼ of 25° C. and under process conditions of nominal (Typ), SS (Slow-Slow), FF (Fast-Fast), FS (Fast-Slow), and SF (Slow-Fast). Also, the inventor of this application performed the simulation under a process condition of nominal and with a junction temperature Tⱼ of 25° C. and a power supply voltage VDD of minimum 1.0 V and maximum 1.2 V. Further, the inventor of this application performed the simulation under a process condition of nominal and with a power supply voltage VDD of 1.1 V and a junction temperature Tⱼ of minimum −40° C. and maximum 125° C.

The dotted broken line represents the Min pulse width when the holding state of the counter circuit is changed from H to L, that is, from 1 to 0. The solid broken line represents the Min pulse width when the holding state of the counter circuit is changed from L to H, that is, from 0 to 1. From the simulation results, it can be seen that the Min pulse width varies depending the influence of the holding state of the counter circuit, the process, and others.

The influence of the holding state of the counter circuit on the Min pulse width will be described with respect to an example in which the process condition is nominal. The Min pulse width is 40 ps when the holding state of the counter circuit is changed from “1” to “0”, and is 30 ps when the holding state of the counter circuit is changed from “0” to “1”. Therefore, when a pulse with a pulse width between 30 ps and 40 ps is input, the holding state of the counter circuit cannot change from “1” to “0”, but it can change from “0” to “1”. Therefore, when a pulse with such a pulse width is input, the holding state of the counter circuit is always “1”. Also, since the Min pulse width varies depending on the process, the power supply voltage VDD, and the junction temperature Tⱼ as described above, the stable counting operation cannot be guaranteed.

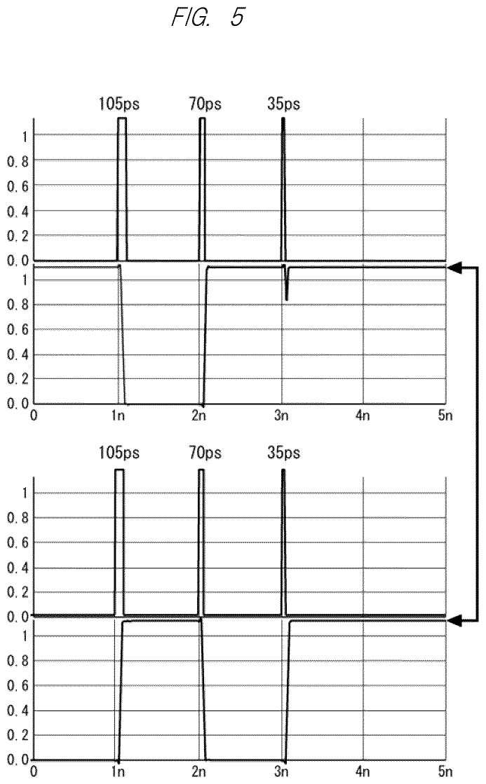

Referring to FIG. 5, the second graph from the top and the fourth graph from the top each illustrate the output waveform of the counter circuit connected to the even-stage ring circuit. The initial holding state of the counter circuit is “1” in the second graph from the top, and the initial holding state of the counter circuit is “0” in the fourth graph from the top. The first graph and the third graph from the top illustrate the waveform of the pulse input to the counter circuit. Referring to the second graph from the top, the counter output does not change due to the pulse with a pulse width of 35 ps, but referring to the fourth graph from the top, the counter output changes from “0” to “1” due to the pulse with a pulse width of 35 ps. In this way, there is a possibility that the output of the counter circuit will always be “1”.

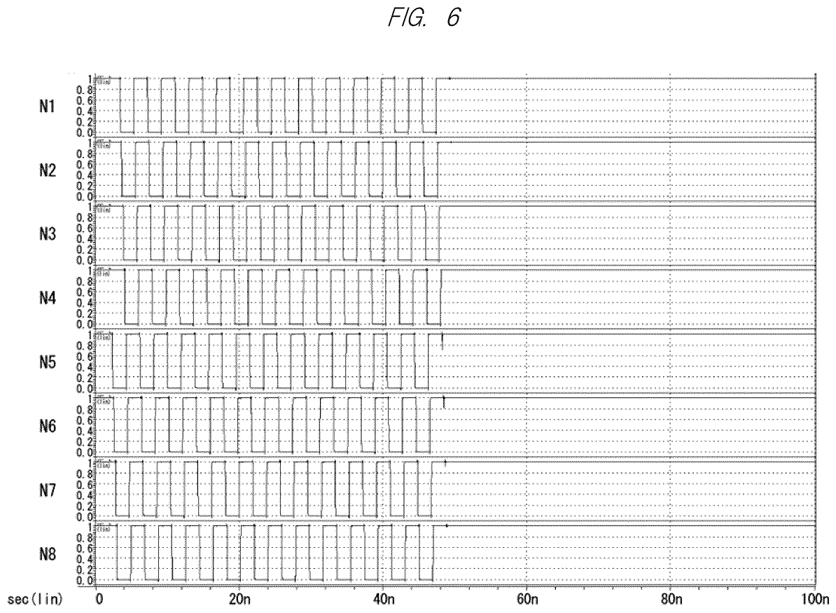

FIG. 6 illustrates the results of the simulation of the count value when a counter circuit is connected to each of the nodes N1 to N8 of the even-stage ring circuit of FIG. 1 and a pulse is generated. The process condition was SS, the power supply voltage VDD was 1.0 V, and the junction temperature Tⱼ was −40° C. The outputs of the 1-bit counters of all the nodes are 1. This is because the Min pulse width depends on the holding state of the counter circuit. In the even-stage ring circuit that generates a pulse with a small pulse width, this problem occurs frequently, so it is difficult to generate the true random number seed using the even-stage ring circuit.

### First Embodiment

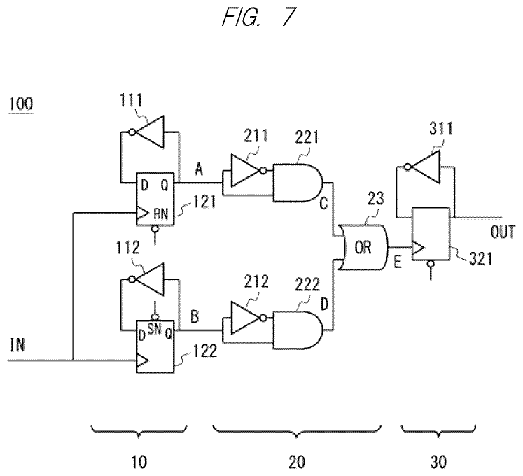

FIG. 7 is a circuit diagram illustrating a semiconductor device 100 according to the first embodiment. The semiconductor device 100 includes a pulse input circuit 10, an edge detection circuit 20, and a counter circuit 30.

The pulse input circuit 10 includes front-stage counters 121 and 122 and NOT gates 111 and 112.

The front-stage counter 121 includes a reset terminal (RN), a pulse input terminal, a data input terminal (D), and an output terminal (Q). The NOT gate 111 inverts an output A of the output terminal of the front-stage counter 121 and outputs it to the data input terminal. A pulse IN (referred to also as first pulse) output from the even-stage ring circuit is input to the pulse input terminal. In the initial state of the front-stage counter 121, the holding state of the front-stage counter 121, that is, the output A is reset to “0” based on the signal input to the reset terminal. The front-stage counter 121 outputs the 1-bit count value of the pulse IN input to the pulse input terminal as the output A. The pulse input terminal may be a clock input terminal.

The front-stage counter 122 includes a set terminal (SN), a pulse input terminal, a data input terminal (D), and an output terminal (Q). The NOT gate 112 inverts an output B of the output terminal of the front-stage counter 122 and outputs it to the data input terminal. A pulse IN output from the even-stage ring circuit is input to the pulse input terminal. In the initial state of the front-stage counter 122, the holding state of the front-stage counter 122 is set to “1” based on the signal input to the set terminal. The front-stage counter 122 outputs the 1-bit count value of the pulse IN input to the pulse input terminal as the output B.

The front-stage counters 121 and 122 are composed of flip-flops. Rear-stage counters 321 to 323, which will be described later, are also composed of flip-flops.

The edge detection circuit 20 includes NOT gates 211 and 212, AND gates 221 and 222, and an OR gate 23.

The NOT gate 211 (referred to also as delay element) delays and inverts the output A of the front-stage counter 121. The delay amount may be, for example, 70 ps. The AND gate 221 outputs the logical AND of the output of the NOT gate 211 and the output A of the front-stage counter 121 as a pulse C. The pulse C has a pulse width according to the delay amount generated by the NOT gate 211. This pulse width is set to be large enough to change the output of the counter circuit 30 regardless of the holding state of the counter circuit 30. In other words, this pulse width needs to be set to be larger than a certain threshold value (predetermined value). The AND gate 221 detects a rising edge of the output A of the front-stage counter 121 and outputs the pulse C based on the edge.

The NOT gate 212 (referred to also as delay element) delays and inverts the output B of the front-stage counter 122. The delay amount may be, for example, 70 ps. The AND gate 222 outputs the logical AND of the output of the NOT gate 212 and the output B of the front-stage counter 122 as a pulse D. The pulse D has a pulse width according to the delay amount generated by the NOT gate 212. This pulse width is set to be large enough to change the output of the counter circuit 30 regardless of the holding state of the counter circuit 30. The AND gate 222 detects a rising edge of the output B of the front-stage counter 122 and outputs the pulse D based on the edge.

The OR gate 23 outputs the logical OR of the pulse C output from the AND gate 221 and the pulse D output from the AND gate 222 as a pulse E (referred to also as second pulse). A pulse width of the pulse E is equal to the pulse width of the pulse C and the pulse width of the pulse D.

The counter circuit 30 includes the rear-stage counter 321 and a NOT gate 311. The NOT gate 311 inverts the output OUT of the output terminal of the rear-stage counter 321 and outputs it to the data input terminal. The pulse E is input to the pulse input terminal of the rear-stage counter 321. The rear-stage counter 321 may also include a set terminal and a reset terminal. The rear-stage counter 321 outputs the 1-bit count value of the pulse E as the output OUT.

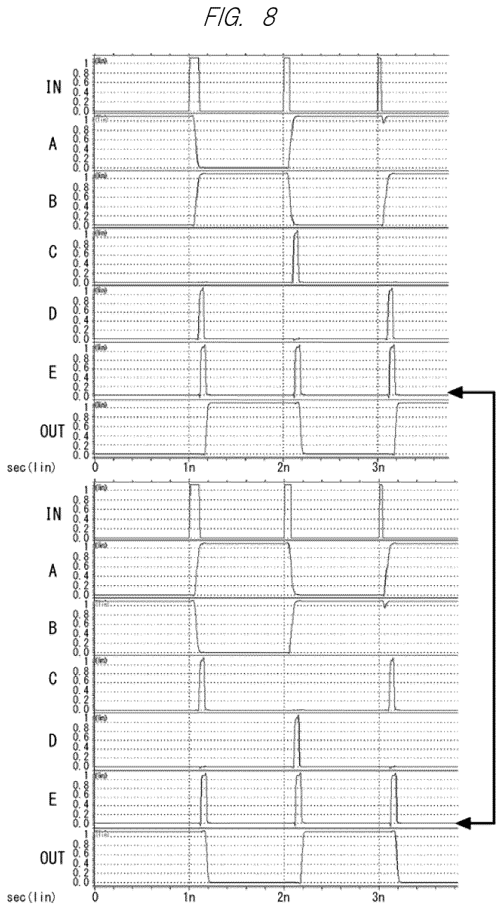

FIG. 8 illustrates the results of the simulation of the operation of the semiconductor device 100. The time chart in the upper part of FIG. 8 illustrates the simulation results when the holding state of the rear-stage counter 321 before the first pulse is input to the semiconductor device 100, that is, the output OUT is “0”. The time chart in the lower part of FIG. 8 illustrates the simulation results when the holding state of the rear-stage counter 321 before the first pulse is input, that is, the output OUT is “1”.

The pulse width of the pulse IN gradually decreases in the order of 105 ps, 70 ps, and 35 ps. Referring to the upper time chart, when the pulse width is 35 ps, the output A of the front-stage counter 121 does not change from “1” to “0” due to the influence of the Min pulse width described above. However, even in this case, the edge detection circuit 20 outputs the pulse E, and the output OUT of the rear-stage counter 321 changes from “0” to “1”. Also, referring to the lower time chart, when the pulse width is 35 ps, the output B of the front-stage counter 122 does not change from “1” to “0”, but the edge detection circuit 20 outputs the pulse E, and the output OUT of the rear-stage counter 321 changes from “1” to “0”. Therefore, it can be seen that the problem of the output of the rear-stage counter 321 being fixed to “1”is solved by the first embodiment.

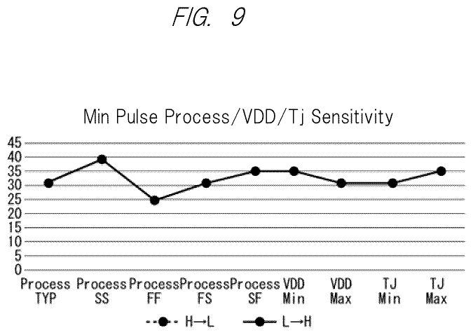

Referring to FIG. 9, the broken line indicating the Min pulse width of the pulse IN when the output OUT of the rear-stage counter 321 changes from “1” to “0” and the broken line indicating the Min pulse width of the pulse IN when the output OUT changes from “0” to “1” are overlapped with each other, with respect to the variations in the process, the power supply voltage VDD, and the junction temperature Tⱼ. Therefore, the first embodiment can realize a stable counting operation.

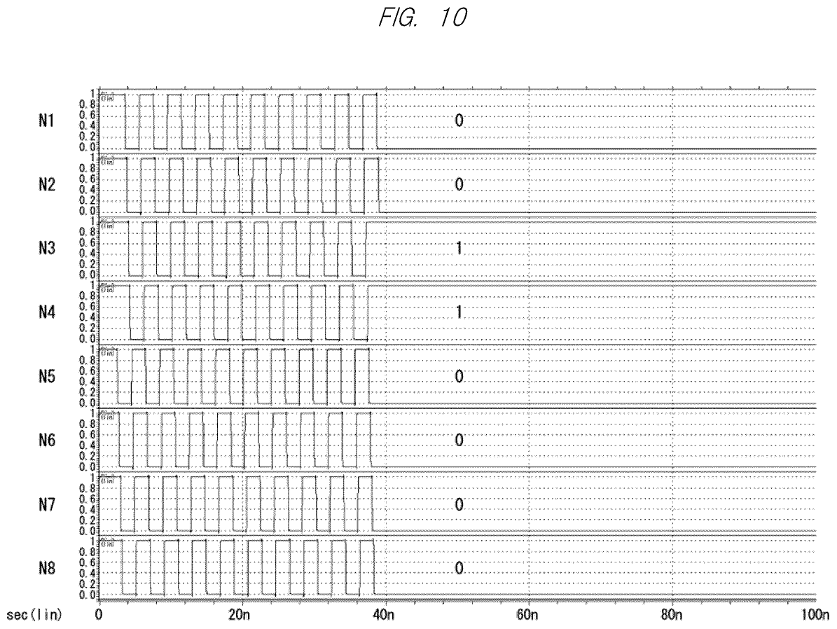

FIG. 10 illustrates the results of the simulation of the output of each semiconductor device 100 when the semiconductor device 100 is attached to each of the nodes N1 to N8 of the even-stage ring circuit in FIG. 1. The phenomenon in which the outputs of all the nodes N1 to N8 become “1”does not occur, and the correct count value is output.

According to the first embodiment, it is possible to stably count the pulses output from the even-stage ring circuit. In the first embodiment, there is no need to perform a transistor-level analysis for each product, and a stable random number generation circuit can be realized in a short time.

### Second Embodiment

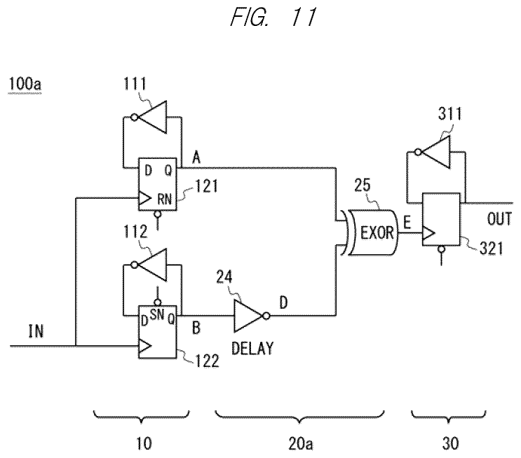

FIG. 11 is a circuit diagram of a semiconductor device 100a according to the second embodiment. Comparing FIG. 7 and FIG. 11, the edge detection circuit 20 is replaced with an edge detection circuit 20a.

The edge detection circuit 20a includes a NOT gate 24 (referred to also as delay element) and an EXOR gate 25. The NOT gate 24 delays and inverts the output B of the front-stage counter 122. The EXOR gate 25 outputs the exclusive OR of the output A of the front-stage counter 121 and the output D of the NOT gate 24 as an output E. The output E of the EXOR gate is input to the rear-stage counter 321.

The edge detection circuit 20a detects the edge of the output A of the front-stage counter 121 and the edge of the output B of the front-stage counter 122. The edge detection circuit 20a is configured to output a pulse having a pulse width according to the delay amount based on the edge. This pulse width is set to be large enough to change the output of the counter circuit 30 regardless of the holding state of the counter circuit 30. Then, when the pulse width of the pulse IN output from the even-stage ring circuit is small and the output A of the front-stage counter 121 or the output B of the front-stage counter 122 does not change, the edge detection circuit 20a is configured to output a stepwise signal. The output OUT of the rear-stage counter 321 changes also when the stepwise signal is input.

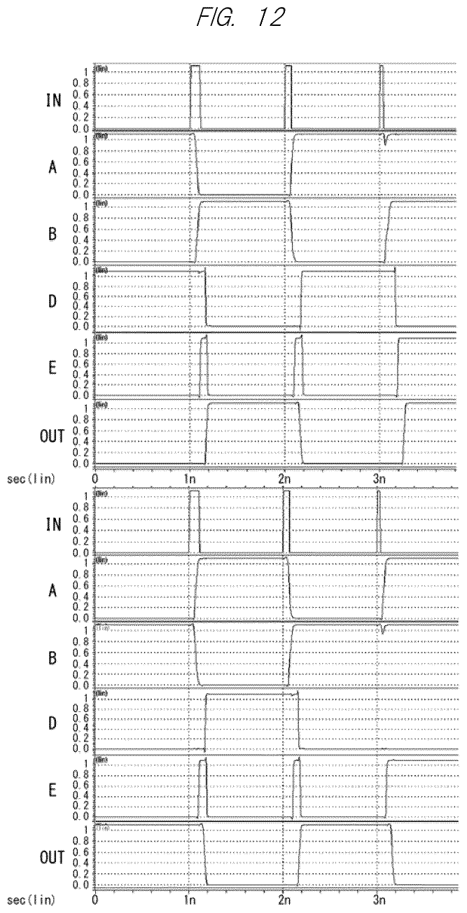

Referring to the time chart in the upper part of FIG. 12, the output A of the front-stage counter 121 does not change due to the pulse with a pulse width of 35 ps, but the output E of the edge detection circuit 20a changes stepwise, and the output OUT of the rear-stage counter 321 changes from “0” to “1”. Also, referring to the time chart in the lower part of FIG. 12, the output B of the front-stage counter 122 does not change due to the pulse with a pulse width of 35 ps, but the output E of the edge detection circuit 20a changes stepwise, and the output OUT of the rear-stage counter 321 changes from “1” to “0”. In this way, the problem of the output OUT of the rear-stage counter 321 being fixed can be solved also by the second embodiment.

Since the second embodiment uses fewer gates than the first embodiment, it can be realized in a small area.

### Third Embodiment

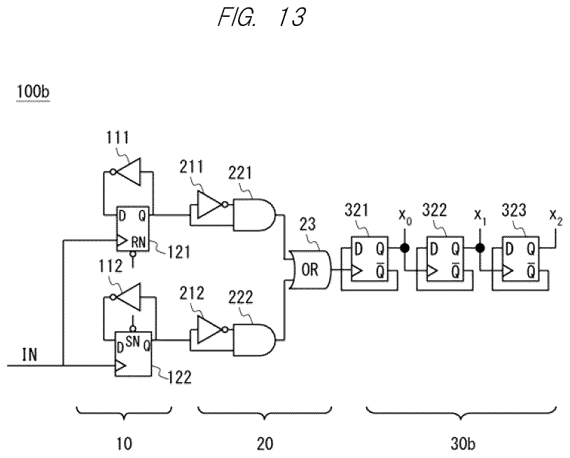

FIG. 13 is a circuit diagram illustrating a semiconductor device 100b according to the third embodiment. Comparing FIG. 7 and FIG. 13, the counter circuit 30 is replaced with a counter circuit 30b. The counter circuit 30b is configured as a multi-bit counter circuit.

For example, the output of the edge detection circuit 20 is input to the pulse input terminal of the rear-stage counter 321. A signal obtained by inverting an output x₀ of the rear-stage counter 321 is input to the data input terminal of the rear-stage counter 321. The output x₀ of the rear-stage counter 321 is input to the pulse input terminal of the rear-stage counter 322. A signal obtained by inverting an output x₁ of the rear-stage counter 322 is input to the data input terminal of the rear-stage counter 322. The output x₁ of the rear-stage counter 322 is input to the pulse input terminal of the rear-stage counter 323. A signal obtained by inverting an output x₂ of the rear-stage counter 323 is input to the data input terminal of the rear-stage counter 323. The count value by counter circuit 30b is determined based on the output x₀ of the rear-stage counter 321, the output x₁ of the rear-stage counter 322, and the output x₃ of the rear-stage counter 323.

The number of rear-stage counters included in the counter circuit 30b may be two or may be four or more. Also, the edge detection circuit 20 in FIG. 13 may be replaced with the edge detection circuit 20a of the second embodiment.

In the third embodiment, pulses output from the even-stage ring circuit can be counted by a multi-bit counter.

In the foregoing, the invention made by the inventor of this application has been specifically described on the basis of the embodiments, but it goes without saying that the present invention is not limited to the embodiments described above and various modifications can be made within the range not departing from the gist thereof.

What is claimed is:

1. A semiconductor device comprising:
a pulse input circuit including flip-flops constituting each of two front-stage counters having different holding states from each other and configured such that first pulses from an even-stage ring circuit are input to each of the two front-stage counters;
an edge detection circuit configured to detect edges of outputs of the two front-stage counters and output a second pulse having a predetermined pulse width larger than a predetermined value based on the edge; and
a counter circuit including a rear-stage counter to which the second pulse is input,
wherein the edge detection circuit is configured to output the second pulse or a stepwise signal when a pulse width of the first pulse is smaller than the predetermined value.

2. The semiconductor device according to claim 1,
wherein one of the two front-stage counters is composed of a flip-flop with a reset function, and
wherein the other of the two front-stage counters is composed of a flip-flop with a set function.

3. The semiconductor device according to claim 1,
wherein the edge detection circuit includes a delay element configured to generate a delay according to the predetermined pulse width, and
wherein the predetermined pulse width is set to be large enough to change an output of the rear-stage counter regardless of a holding state of the rear-stage counter.

4. The semiconductor device according to claim 1,
wherein the edge detection circuit includes:
a first delay element configured to generate a delay according to the predetermined pulse width based on the edge of the output of one of the two front-stage counters;
a second delay element configured to generate a delay according to the predetermined pulse width based on the edge of the output of the other of the two front-stage counters; and
an OR gate configured to output a logical OR of a pulse based on the delay generated by the first delay element and a pulse based on the delay generated by the second delay element as the second pulse.

5. The semiconductor device according to claim 1,
wherein the edge detection circuit includes a delay element configured to delay and invert the output of one of the two front-stage counters, and outputs an exclusive OR of an output from the delay element and the output of the other of the two front-stage counters as the second pulse.

6. The semiconductor device according to claim 1,
wherein the counter circuit is a multi-bit counter.
